(19) United States
(12) Patent Application Publication
(10) Pub. No.: US 2004/0237890 A1
(43) Pub. Date: Dec. 2, 2004

(54) Polyphenylene sulfide protected geothermal steam transportation pipe

(75) Inventor: Daniel L. Bour, Bakersfield, CA (US)

Correspondence Address: CONLEY ROSE, P.C., P. O. BOX 3267, HOUSTON, TX, 77253-3267, US

(73) Assignee: Halliburton Energy Services, Inc., Houston, TX

(21) Appl. No.: 10/447,423

(22) Filed: May 29, 2003

(51) Int. Cl. B05D 3/02; B05D 7/00; C23C 16/00

(52) U.S. Cl. 118/715; 427/230; 427/384; 427/299; 427/402

(57) ABSTRACT

A method and metal equipment for use in wells, wherein metal equipment is used in the operation and drilling of a well, and wherein the metal equipment has a surface. In one embodiment, the method comprises applying a polyphenylene sulfide coating to the surface and curing the polyphenylene sulfide coating. In other embodiments, the method further comprises cleaning the surface before applying the polyphenylene sulfide coating. Additional embodiments include the method further comprising applying a primer coating to the surface.

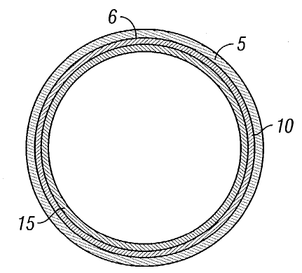

### BACKGROUND OF THE INVENTION

1. Field of the Invention

This invention relates to the field of coatings and more specifically to the field of applying polyphenylene sulfide coatings to pipes.

2. Background of the Invention

In the production and drilling of geothermal wells, transportation pipes are used to transport geothermal steam. Typically, the transportation pipes comprise carbon steel. In operation, the transportation pipes are typically exposed to high temperatures and corrosive materials that may reduce the usable life of the transportation pipes. For instance, the inside of the transportation pipes may be exposed to high temperature fluids for extended periods of time, with the fluids often at temperatures of over 200° C. In addition, corrosive materials such as brine, acids, carbon dioxide, hydrogen sulfide, dissolved minerals, and the like may be transported by the pipes. Over time, the high temperature fluids and corrosive materials can corrode the carbon steel pipes until the transportation pipes can no longer be safely and efficiently used. The corroded transportation pipes then typically are replaced by the same or more expensive pipe, which may also include interrupting operations of the well during replacement of the pipe. By interrupting operations of the well to replace the pipe, plant operations to which the geothermal steam provides heat are typically shut down until the geothermal steam supply is returned. Shutting down plant operations typically has a high cost.

Therefore, it is highly advantageous to extend the useful life of transportation pipe in geothermal wells. Cement lining of the inside of the pipes has been used to protect the transportation pipes against high temperatures and corrosive materials. Typically, the cement lining is about 15 mm thick. Problems encountered include cracking of the cement lining and de-bonding of the cement lining from the pipe, which can lead to exposure of the pipe. Debris in the transportation pipe may impact the cement lining, thereby causing it to crack and de-bond. In addition, vibration of the transportation pipe during operating conditions can also cause the cement lining to crack and de-bond. Moreover, thermal expansion of the pipe and cement lining can cause the cement lining to crack and de-bond. Nickel and nickel alloy coatings have also been applied to the inside of transportation pipes to extend the useful life. However, the nickel and nickel alloy coatings typically corrode and become brittle under the high temperatures and exposure to the corrosive materials. Therefore, the nickel and nickel alloy coatings also tend to crack and de-bond from the transportation pipes. Titanium alloy pipes have also been used as transportation pipes. However, titanium alloy pipes are typically very expensive.

Consequently, there is a need for extending the useful life of transportation pipes in geothermal wells. Further needs include protecting the inside of the transportation pipes from high temperature applications and exposure to corrosive materials. Additional needs include a more efficient and safe coating on the inside of the transportation pipes.

### BRIEF SUMMARY OF SOME OF THE PREFERRED EMBODIMENTS

These and other needs in the art are addressed in one embodiment by an inventive method for protecting metal equipment used in the operation and drilling of a well, wherein the metal equipment has a surface. The method comprises applying a polyphenylene sulfide coating to the surface and curing the polyphenylene sulfide coating.

In another embodiment, the invention comprises cleaning the inside surface of a metal pipe before applying the polyphenylene sulfide coating.

In a third embodiment, the invention comprises metal equipment for use in geothermal wells, wherein the metal equipment has a surface. The metal equipment comprises a polyphenylene sulfide coating adhered to the surface.

In other embodiments, the invention comprises cleaning the inside surface before applying the polyphenylene sulfide coating. Further embodiments include preparing the inside surface before applying the polyphenylene sulfide coating.

It will therefore be seen that a technical advantage of the invention includes a polyphenylene sulfide coating on the inside surface of the steam transportation pipe, thereby eliminating problems associated with the use of cement or nickel coatings. Further advantages include a transportation pipe that can be safely and efficiently used in transporting fluids at high temperatures while being exposed to corrosive materials. Additional advantages include insulating the fluids traveling through the transportation pipe.

The disclosed devices and methods comprise a combination of features and advantages, which enable it to overcome the deficiencies of the prior art devices. The various characteristics described above, as well as other features, will be readily apparent to those skilled in the art upon reading the following detailed description, and by referring to the accompanying drawings.

### BRIEF DESCRIPTION OF THE DRAWINGS

For a detailed description of the preferred embodiments of the invention, reference will now be made to the accompanying drawing, which illustrates a cross-section of a geothermal steam transportation pipe having a primer coating and a PPS coating.

### DETAILED DESCRIPTION OF THE PREFERRED EMBODIMENTS

The drawing illustrates one embodiment of the invention, comprising a cross-section of a geothermal steam transportation pipe 5 having an inside surface 6, on which are a primer coating 10 and an internal PPS coating 15. Transportation pipe 5 may comprise carbon steel, aluminum, or any other suitable metal for use in geothermal wells. Primer coating 10 preferably includes at least one of zinc, zinc alloy, zinc phosphate, nickel, silver, cobalt oxide, manganese, manganese phosphate, and any other suitable primer that prevents oxidation of the inside surface of transportation pipe 5 and/or promotes adhesion of PPS coating 15. Primer coating 10 may have a thickness of at least about 0.01 mm and preferably from about 0.025 mm to about 0.1 mm.

PPS coating 15 comprises polyphenylene sulfide (“PPS”) that has been cured. In alternative embodiments, PPS coating 15 may also comprise at least one filler. The filler comprises materials that include at least one of cement, propylene glycol, TiO₂, cobalt oxide, polytetrafluoroethylene (“PTFE”), glass fibers, and any other filler suitable for use with a PPS coating and capable of withstanding curing temperatures and the operating conditions of geothermal wells. PPS coating 15 may have a thickness of at least about 0.01 mm and preferably from about 0.05 mm to about 0.15 mm.

The following describes an exemplary application of the present invention as illustrated in the drawing. The pipes to be used as transportation pipe 5 in geothermal wells typically have contaminants deposited on their inside surface as a result of manufacturing, transportation, or the like. These contaminants may comprise rust, minerals, oils, greases, and the like. Before application of the coatings 10 and 15 to inside surface 6 of transportation pipe 5, inside surface 6 is preferably cleaned of these contaminants. The techniques for cleaning the inside surface of pipes are well known in the art and include vapor degreasing, sonic degreasing, solvent washing, heat degradation, and any other suitable technique for removing the contaminants.

After inside surface 6 is clean, it can be prepared for application of the coatings 10 and 15. In an alternative embodiment, inside surface 6 is only partially cleaned, or is not cleaned before preparation. The inside surface 6 of transportation pipe 5 is typically slightly rough or uneven. Preparation of inside surface 6 can therefore also include smoothing the uneven surface so as to provide a substantially smooth inside surface 6. The inside surface 6 can be prepared by known blasting techniques, such as sandblasting, gritblasting, and the like. The blasting technique, if used, is preferably applied for a time and with a pressure sufficient to substantially smooth inside surface 6. In alternative embodiments, chemical treatments may also be used, alone or in combination with other surface treatments, to prepare inside surface 6. The chemical treatments can include acids, solvents and the like. Other alternative embodiments include preparing the inside surface 6 by filling with preparation filling materials any notches, holes, indentations, and the like that may be present in the inside surface 6. The preparation filling materials can include cement, epoxies and any other suitable material that can withstand the curing temperatures and conditions of geothermal wells. In other alternative embodiments, welds can be used to fill the notches, holes, indentations, and the like. If desired, transportation pipe 5 may again be cleaned after preparation of its inside surface 6.

After inside surface 6 of transportation pipe 5 has been cleaned and/or prepared, primer coating 10 can be applied to inside surface 6 and dried or cured so as to adhere to inside surface 6. In alternative embodiments, primer coating 10 can be applied without cleaning inside surface 6 and/or or without preparing inside surface 6. Primer coating 10 can be applied to inside surface 6 by any suitable primer application technique. Suitable primer application techniques include spraying, fill and drain treatment, and other techniques, such as are known in the art. The fill and drain technique includes using a valve or other device to close one end of transportation pipe 5 and then pouring the primer into the open end of transportation pipe 5. After transportation pipe 5 is filled and inside surface 6 is fully coated, the excess primer is drained from the pipe, and the remaining primer coating 10 is cured.

The curing of primer coating 10 is dependent on the thickness of the coating, the temperature, and the time. For instance, a primer coating 10 having a thickness of about 0.025 mm can be air dried for about 10 minutes and then baked at a temperature of from about 60° C. to about 80° C. for about 15 minutes. Primer coating 10 can then be cured at a temperature of about 175° C. for about 30 minutes. These temperatures and times are representative only and do not limit the invention. In alternative embodiments, primer coating 10 can be applied to inside surface 6 in a plurality of coats, with the primer being cured or partially cured after each coat is applied. In other alternative embodiments, the primer may not be air dried and may not be baked before curing. Further alternative embodiments include air drying or baking the primer before curing.

After primer coating 10 has been applied, PPS coating 15 is applied to primer coating 10 and then cured so as to adhere to the surface of primer coating 10. In alternative embodiments, PPS coating 15 can be applied to inside surface 6 without a primer coating. Other alternative embodiments include applying PPS coating 15 without cleaning inside surface 6 and/or without preparing inside surface 6.

PPS coating 15 can be applied by known PPS application techniques. Suitable PPS application techniques include slurry coating, electrostatic coating, fill and drain treatment, powder spraying, and any other suitable technique for applying PPS coating 15. Slurry coating techniques comprise using a slurry sprayer to apply a water-based liquid slurry of PPS. Electrostatic coating techniques comprise using an electrostatic sprayer to apply the PPS coating. Powder spraying comprises applying the PPS in powder form using a powder sprayer such as a flocking gun or other powder sprayer.

After the PPS is applied to the desired thickness, the PPS can be cured. The curing of PPS coating 15 is dependent on the thickness of the coating, the temperature, and the time. PPS coating 15 may be cured at increasing temperatures until the desired flexibility and adhesion are obtained. For instance, a coating thickness of about 0.25 mm may be cured at a temperature of about 315° C. for up to about 72 hours, 340° C. for from about 12 hours to about 48 hours, about 370° C. for from about 1.5 hours to about 12 hours, about 400° C. for from about 1 hour to about 6 hours, and about 430° C. for from about 30 minutes to about 2 hours. These temperatures and times are representative only and do not limit the invention. In alternative embodiments, PPS coating 15 can be applied in a plurality of coats, with the PPS being cured or partially cured after each coat is applied.

In alternative embodiments (not illustrated), primer coating 10 and PPS coating 15 can be applied to other metal equipment used in geothermal wells in addition to transportation pipes 5. The coatings 10 and 15 can be applied to the metal equipment in the manner as described above. The metal equipment may include valves, compressors, and the like. In some embodiments, PPS coating 15 may be applied to the metal equipment without primer coating 10.

Even though the above disclosure describes applying PPS to protect geothermal steam transportation pipes and metal equipment, the present invention is not limited to such applications and may be useful in other applications. The present invention would prove useful, for example, in protecting any pipes exposed to high temperatures and corrosive materials. For instance, PPS coating 15 may protect pipes, casing strings, coiled tubing, jointed tubing, surface irons, and the like in oil and gas well operations and any other applications whereby high temperature and corrosive conditions are present. In addition, PPS coating 15 may protect valves, tanks, pumps, and the like that are exposed to the conditions in oil and gas well operations and any other applications whereby high temperature and corrosive conditions are present.

Although the present invention and its advantages have been described in detail, it should be understood that various changes, substitutions and alterations may be made herein without departing from the spirit and scope of the invention as defined by the appended claims.

What is claimed is:

1. A method of protecting metal equipment used in the operation and drilling of a well, wherein the metal equipment has a surface, the method comprising:
(A) applying a polyphenylene sulfide coating to the surface; and
(B) curing the polyphenylene sulfide coating.

2. The method of claim 1, wherein the wells comprise oil, gas, and geothermal wells.

3. The method of claim 1, wherein the well is a geothermal well and the surface is the inside surface of a length of pipe.

4. The method of claim 1, wherein the metal equipment comprises transportation pipe, valves, compressors, casing strings, coiled tubing, jointed tubing, tanks, pumps, and surface irons.

5. The method of claim 1, wherein step (A) further comprises cleaning the surface before applying the polyphenylene sulfide coating.

6. The method of claim 5, further comprising preparing the surface before applying the polyphenylene sulfide coating.

7. The method of claim 6, further comprising applying a primer coating to the surface before applying the polyphenylene sulfide coating, the polyphenylene sulfide coating applied to the primer coating.

8. The method of claim 7, further comprising curing the primer coating.

9. The method of claim 1, wherein step (A) further comprises preparing the surface before applying the polyphenylene sulfide coating.

10. The method of claim 9, further comprising applying a primer coating to the surface before applying the polyphenylene sulfide coating, the polyphenylene sulfide coating applied to the primer coating.

11. The method of claim 10, further comprising curing the primer coating.

12. The method of claim 1, wherein step (A) further comprises applying a primer coating to the surface before applying the polyphenylene sulfide coating, the polyphenylene sulfide coating applied to the primer coating.

13. The method of claim 12, further comprising curing the primer coating.

14. A method of protecting a metal pipe using a polyphenylene sulfide coating, wherein the metal pipe has an inside surface, the method comprising:
(A) cleaning the inside surface;
(B) applying the polyphenylene sulfide coating to the inside surface; and
(C) curing the polyphenylene sulfide coating.

15. The method of claim 14, wherein the metal pipe is used in at least one of oil, gas, and geothermal wells.

16. The method of claim 14, wherein step (A) is accomplished by at least one technique selected from the group consisting of: vapor degreasing, sonic degreasing, solvent washing, and heat degradation.

17. The method of claim 14, wherein step (A) further comprises preparing the inside surface.

18. The method of claim 17, wherein preparing the inside surface is accomplished by at least one technique selected from the group consisting of:
(1) blasting; and
(2) chemical treatment.

19. The method of claim 18, further comprising preparing the inside surface with at least one of a preparation filling material and welds.

20. The method of claim 17, further comprising applying a primer coating to the inside surface, wherein the primer coating is cured.

21. The method of claim 14, wherein step (B) further comprises applying a primer coating to the inside surface before applying the polyphenylene sulfide coating, the polyphenylene sulfide coating applied to the primer coating.

22. The method of claim 21, further comprising applying the primer coating by at least one technique selected from the group consisting of:
(1) spraying; and
(2) fill and drain treatment.

23. The method of claim 21, further comprising curing the primer coating.

24. The method of claim 21, wherein the primer coating has a thickness of at least about 0.01 mm.

25. The method of claim 21, wherein the primer coating comprises at least one primer selected from the group consisting of: zinc, zinc alloy, zinc phosphate, nickel, silver, cobalt oxide, manganese and manganese phosphate.

26. The method of claim 14, wherein step (B) further comprises the polyphenylene sulfide coating having a thickness of at least about 0.01 mm.

27. The method of claim 14, wherein step (B) further comprises the polyphenylene sulfide coating comprising at least one filler.

28. The method of claim 27, wherein the filler comprises at least one material selected from the group consisting of: cement, propylene glycol, TiO₂, cobalt oxide, PTFE, and glass fibers.

29. The method of claim 14, wherein step (B) further comprises applying the polyphenylene sulfide by at least one technique selected from the group consisting of: slurry coating, electrostatic coating, fill and drain treatment, and powder spraying.

30. Metal equipment for use in geothermal wells, wherein the metal equipment has a surface, the metal equipment comprising:
a polyphenylene sulfide coating adhered to the surface.

31. The metal equipment of claim 30, wherein the metal equipment comprises transportation pipe, valves, and compressors.

32. The metal equipment of claim 30, wherein the surface is an inside surface of the metal equipment.

33. The metal equipment of claim 30, wherein the polyphenylene sulfide coating has a thickness of at least about 0.01 mm.

34. The metal equipment of claim 30, wherein the polyphenylene sulfide coating comprises at, least one filler.

35. The metal equipment of claim 34, wherein the filler comprises at least one material selected from the group consisting of: cement, propylene glycol, TiO₂, cobalt oxide, PTFE and glass fibers.

36. The metal equipment of claim 30, wherein the metal equipment further comprises a primer coating disposed between the polyphenylene sulfide coating and the surface, wherein the primer coating is adhered to the surface, and wherein the polyphenylene sulfide coating is adhered to the primer coating.

37. The metal equipment of claim 36, wherein the primer coating has a thickness of at least about 0.01 mm.

38. The metal equipment of claim 36, wherein the primer coating comprises at least one primer selected from the group consisting of: zinc, zinc alloy, zinc phosphate, nickel, silver, cobalt oxide, manganese and manganese phosphate.
